(19) United States
(12) Patent Application Publication
(10) Pub. No.: US 2025/0140447 A1
(43) Pub. Date: May 1, 2025

(54) COUPLED CONDUCTORS IN TWINAX CABLE AND STRIPLINE PRINTED CIRCUIT BOARD FOR SKEW MITIGATION

(71) Applicant: Cisco Technology, Inc., San Jose, CA (US)

(72) Inventors: Mike Sapozhnikov, San Jose, CA (US); Amendra Koul, San Francisco, CA (US); David Nozadze, San Jose, CA (US); Joel Richard Goergen, Soulsbyville, CA (US); Sayed Ashraf Mamun, San Jose, CA (US); Upen Reddy Kareti, Union City, CA (US)

(21) Appl. No.: 18/418,694

(22) Filed: Jan. 22, 2024

Related U.S. Application Data
(60) Provisional application No. 63/593,019, filed on Oct. 25, 2023.

(51) Int. Cl. H01B 11/20; H01B 7/08; H01B 11/04; H01P 3/08; H05K 1/02

(52) U.S. Cl. CPC H01B 11/203; H01B 7/0807; H01B 7/0823; H01B 7/0838; H01B 11/04; H01P 3/08; H05K 1/0228

(57) ABSTRACT

Techniques are provided to mitigate serializer-deserializer performance limiting positive/negative (P/N) skew issues in high-speed cable channels. This may be achieved by adding stripes with low/high dielectric constant (dk) material compared to the main dielectric surrounding cable wires. By adding strips/stripes in the main dielectric, a non-homogeneous dielectric structure is created, and this results in greater coupling between the signal conductors in the cable, which in turn reduces skew impact. This may be useful in twinaxial cables as well as stripline printed circuit boards.

### PRIORITY CLAIM

This application claims priority to U.S. Provisional Application No. 63/593,019, filed Oct. 25, 2023, the entirety of which is incorporated herein by reference.

### TECHNICAL FIELD

The present disclosure relates to skew mitigation in twinaxial (twinax) cables and in stripline printed circuit boards (PCBs).

### BACKGROUND

The rapid growth of data centers, among other developments, has pushed the demand for networks with increasingly higher data rates. With increasing data rates, the unit interval (UI) decreases. The unit interval is the minimum time interval between condition changes of a data transmission signal, also known as the pulse time or symbol duration time. For example, 224 Gigabits/sec (G), 4-Level Pulse Amplitude Modulation (PAM4) signaling has an approximately 9 picosecond (picoseconds (ps) UI.

The differential intra-pair skew that is unintentionally present within a differential pair (in both a printed circuit board and a twinaxial (twinax) cable) has become a fundamental performance limiting issue for high-speed serial-communication links. Intra-pair skew causes channel differential insertion loss (IL) to increase. When skew is equal to the UI, differential IL is dramatically large, In theory, it is infinity at the fundamental frequency, which is 56 GHz for 224G PAM4 signaling. Therefore, for small UI (i.e. 9 picoseconds (ps)), a few picoseconds of skew can lead system failure.

### BRIEF DESCRIPTION OF THE DRAWINGS

FIG. 1 illustrates a plot that depicts differential insertion loss due to skew versus frequency in a twinax cable.

FIG. 2 illustrates a cross-section of a conventional twinaxial cable with a homogeneous dielectric.

FIG. 3 illustrates plots depicting velocity of even and odd mode signals in a twinax cable with the homogeneous dielectric properties of FIG. 2.

FIG. 4 illustrates a cross-section of a twinaxial cable having a non-homogeneous dielectric, according to an example embodiment.

FIG. 5 illustrates plots depicting velocity of even and odd mode signals in a twinax cable with the non-homogeneous dielectric properties of FIG. 4, according to an example embodiment.

FIG. 6 is a diagram depicting the benefits of improved coupling of energy between conductors as a result of the non-homogeneous dielectric, such as shown in FIG. 4, according to an example embodiment.

FIG. 7 illustrates plots comparing coupling between signal conductors of a cable having a homogeneous dielectric structure (as shown in FIG. 2) with the coupling between signal conductors of a cable having a non-homogeneous dielectric structure (as shown in FIG. 4).

FIG. 8 illustrates plots comparing the skew impact on differential insertion loss for a cable having a homogeneous dielectric structure (as shown in FIG. 2) with the skew impact on differential loss for a cable having a non-homogeneous dielectric structure (as shown in FIG. 4).

FIGS. 9A, 9B, 10A and 10B illustrate cross-sectional views showing variations to the sizes and spacing of the strips created in the dielectric to induce a non-homogenous dielectric property, according to example embodiments.

FIG. 11 is a cross-sectional view of a stripline printed circuit board having a non-homogeneous dielectric structure formed by dielectric layers having different dielectric constants, according to an example embodiment.

FIG. 12A is a cross-sectional view of a stripline printed circuit board having a non-homogeneous dielectric structure formed by a dielectric strip, with a lower dielectric constant, disposed between conductive signal traces, according to an example embodiment.

FIG. 12B is a perspective transparent view of the stripline printed circuit board of FIG. 12A.

FIG. 12C is a cross-sectional view of a stripline printed circuit board having a non-homogeneous dielectric structure formed by a dielectric strip disposed between conductive signal traces and a plurality of strips beneath the conductive signal traces, according to an example embodiment.

FIG. 12D is a perspective transparent view of the stripline printed circuit board of FIG. 12C.

### DETAILED DESCRIPTION

### Overview

Techniques are provided to mitigate intra-pair skew in high-speed twinaxial (twinax) cables. Based on research it has been determined that a strongly coupling between conductors in a twinax cable (and between conductive traces in a stripline printed circuit board) should be created to mitigate intra-pair skew between conductors of a differential conductor pair. Configurations are presented herein to create strong coupling between conductors in a twinax cable and stripline printed circuit board.

In one form, an apparatus is provided that comprises a dielectric body, first and second conductors within the dielectric body spaced apart from each other, and a shield around a periphery of the dielectric body. The dielectric body has, in cross-section, a non-homogenous dielectric property configured to enhance coupling of electromagnetic energy between the first and second conductors when signals are carried by the first and second conductors.

In one example, the apparatus is a cable and the dielectric body comprises, in cross-section, a first portion with a first dielectric constant and a second portion with a second dielectric constant different from the first dielectric constant. The second portion is proximate the shield and the second dielectric constant is less than the first dielectric constant so as to disrupt coupling of electromagnetic energy towards the shield and thereby enhance coupling of electromagnetic energy between the first and second conductors.

In another example, the apparatus is a stripline printed circuit board, and wherein the first and second conductors are first and second conductive signal traces in the dielectric body. In one form, the dielectric body may comprise, in cross-section, a first dielectric layer having a first dielectric constant and a second dielectric layer having a second dielectric constant. The first and second conductive signal traces are formed in the first dielectric layer and the second dielectric layer is adjacent the first dielectric layer. The first dielectric constant is greater than the second dielectric constant. In another form, the dielectric body may comprise, in cross-section, a first dielectric layer having a first dielectric constant and a second dielectric layer having a first dielectric constant. The first and second conductive signal traces are formed in the first dielectric layer and the second dielectric layer is adjacent the first dielectric layer. A dielectric strip is disposed between the first and second conductive signal traces, the dielectric strip having a second dielectric constant that is less than the first dielectric constant. Further still, a plurality of strips may be disposed beneath the first dielectric layer that extend into the second dielectric layer. The plurality of strips comprising spaced apart air gaps or a material having a dielectric constant less than the first dielectric constant.

### EXAMPLE EMBODIMENTS

The unintended presentation of intra-pair differential skew within a differential conductor pair is a performance-limiting issue for high-speed serializer-deserializer (serdes) applications, such as 56G-224G. Intra-pair skew can dramatically increase differential insertion loss and mode conversion, leading to serdes performance bottlenecks. Homogenous cables can exhibit high skew impact like in a stripline. It is desirable to mitigate the intra-pair skew within high-speed cables and in stripline printed circuit board (PCB).

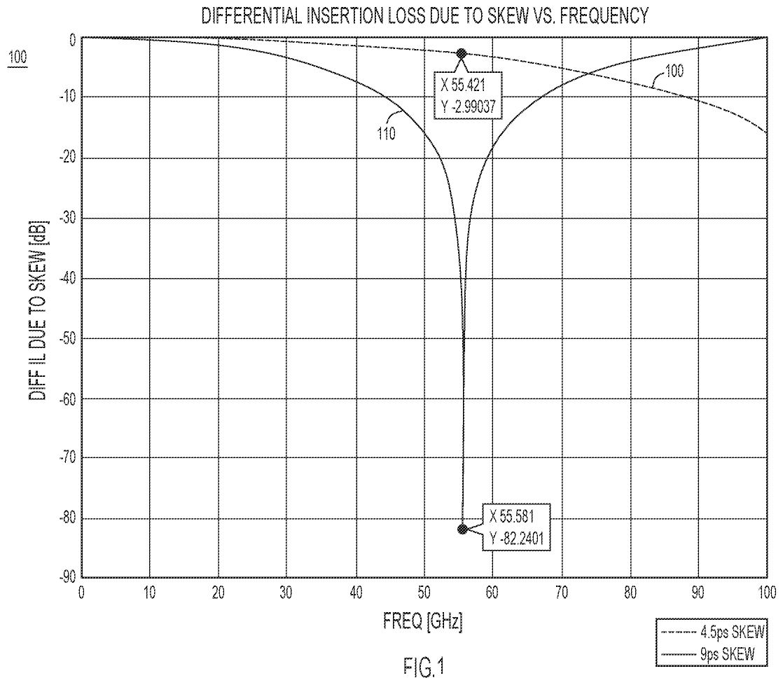

FIG. 1 illustrates plots that show the differential insertion loss due to skew versus frequency. There is a plot 100 shown for 4.5 ps skew and a plot 110 for 9 ps skew. Plot 100 shows that the insertion loss becomes noticeable at around 54 GHz. Plot 110 shows that the insertion loss becomes significant at that same frequency to the point that all signal components may be lost, which will have a substantial impact on receiver performance.

The methods and arrangements presented herein mitigate skew by creating higher coupling between conductors in twinax cables and stripline PCBs. This may be achieved by adding strips/stripes with lower dielectric constant (dk) material compared to the main dielectric surrounding cable wires/conductors. By adding strips/stripes in cable main dielectric, a non-homogeneous dielectric structure is created, and this results in greater coupling between the conductors in the cable (or conductive traces in a stripline PCB), which in turn reduces skew impact.

FIG. 2 shows a cross section of a conventional twinax cable 200 with a homogeneous dielectric structure. The cable 200 includes an outer shield 210, two conductor signal wires 212 and 214 and a dielectric material 216 occupying the body of the cable around and between the conductor signal wires 212 and 214. The conductor signal wires 212 and 214 may be carry differential signals. The dielectric material 216 is homogeneous throughout the body of the cable. That is, the space around and between the conductors is filled with dielectric material 216 that has the same dielectric constant throughout the cross-section of the body of the cable 200.

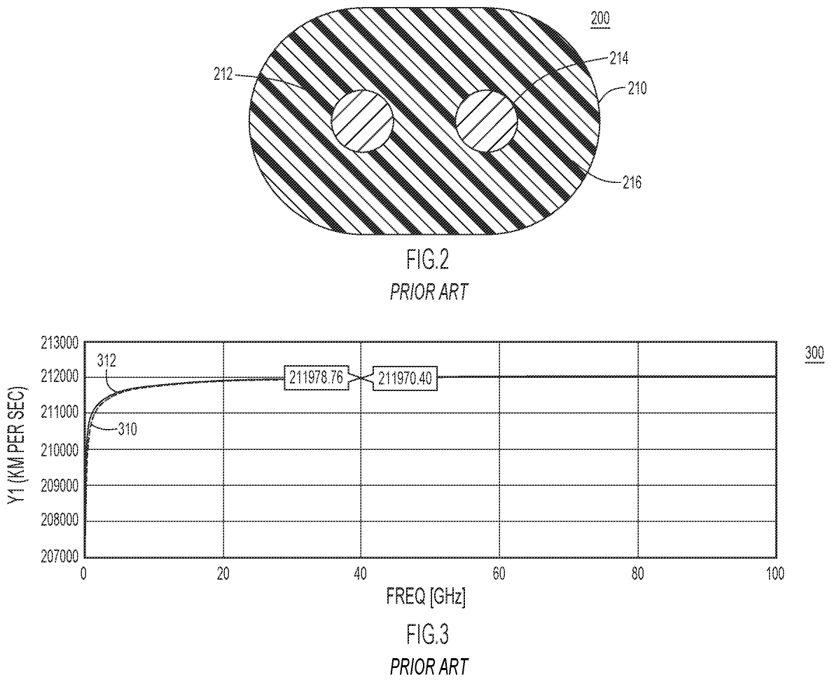

In the cable structure shown in FIG. 2, even and odd mode signals travel with almost the same velocities. The coupling between the conductors is very small for the cable structure shown in FIG. 2, because the dielectric is homogeneous throughout the cross-section of the cable body. FIG. 3 shows plots 300 of even and odd mode velocities of signals in cable 200. There are two curves 310 and 312 in FIG. 3, where curve 310 is for odd mode signals and curve 312 is for even mode signals. These curves overlap so closely that they are barely distinguishable from each other. Because the coupling between the conductor signal wires 212 and 214 is small, then it is not possible to mitigate the skew of the signals on the conductor signal wires 212 and 214. One signal through one conductor signal wire will always be faster than the other signal through the other conductor signal wire.

In order to mitigate skew and minimize its impact, strongly coupled twinax pairs are created according to the embodiments presented herein. That is, the twinax pairs are designed/arranged to have a large electrical coupling between positive (P) and negative (N) conductors of the differential pair. In the signal conductor (i.e., the P conductor) where signal is forward and strongly coupled to the signal in the other conductor (i.e. N), energy is transferred/coupled to second conductor (N) in which the signal is delayed, and this compensates for skew. When the energy is coupled between conductors, if a first signal on a first conductor is faster than a second signal (the differential counterpart signal to the first signal) on the second conductor, the second signal can “catch-up” to the first signal, thus reducing the timing skew between them, which in turn reduces the insertion loss.

Greater coupling between signal conductors can be achieved by creating a non-homogenous dielectric around signal conductors. The non-homogenous dielectric in the body of the cable will result in the even and odd modes having different velocities through the conductors. The greater the difference of the velocities between the even and odd modes, the greater the coupling between signals carried by the respective conductors in the cable. Even and odd modes fields of electromagnetic energy flowing through the conductors will experience a different environment.

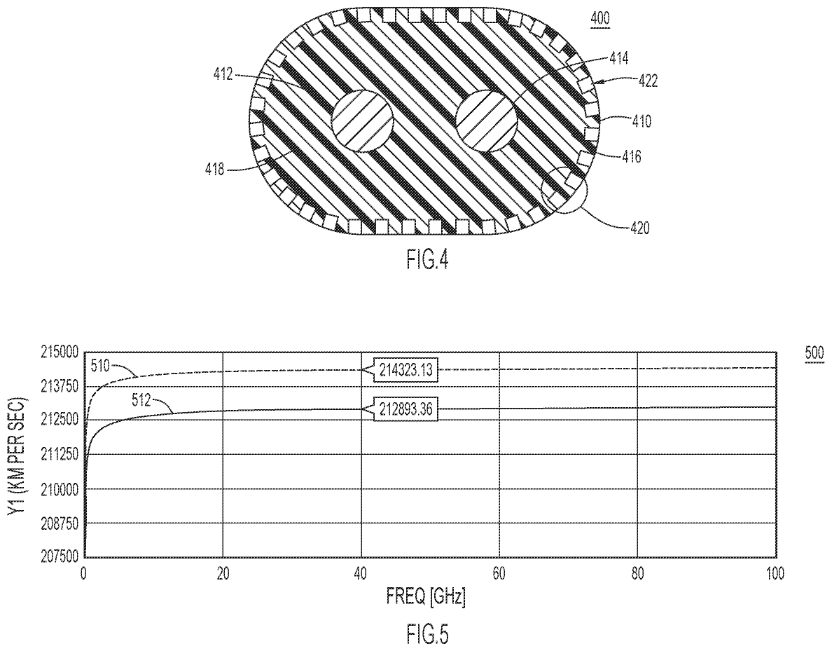

To this end, FIG. 4 illustrates a configuration of a twinax cable 400 in which a non-homogenous dielectric structure is provided in the space between and around the conductors. The cable 400 includes an outer shield 410, first and second conductors 412 and 414 and a dielectric body 416. The dielectric body 416 has, in cross-section, a non-homogeneous dielectric property/characteristic that is configured to enhance coupling of electromagnetic energy between the first and second conductors when signals are carried by the first and second conductors 412 and 414. The shield 410 contains the dielectric body 416.

In one embodiment, to achieve the non-homogenous dielectric property/characteristic of the dielectric body 416, the dielectric body 416 comprises, in cross-section, a first portion 418 with a first dielectric constant and a second portion 420 with a second dielectric constant that is different from the first dielectric constant. The second portion 420 may be proximate the outer shield 410 and may occupy a space or layer adjacent to an inner surface of the outer shield 410. The second dielectric constant of the second portion 420 is less than the first dielectric constant of the first portion 418 so as to disrupt coupling of electromagnetic energy towards the shield 410 and thereby enhance coupling of electromagnetic energy between the first and second conductors 412 and 414.

In one example, the second portion 420 is created by cutting strips or stripes 422 around an edge of the dielectric material that is adjacent to the shield 410. These strips can be empty (air gaps) or filled with material with a different dielectric constant less than that of the dielectric material used in cables for the body portion 418. For example, the cable dielectric constant (dk) is around 2.1 and thus the second portion would have a dielectric constant less than 2.1, which can be the result of the strips of shape air gaps or strips of other dielectric material with a lower dielectric constant than 2.1. The size of the individual strips may be 1 mil×1 mil, as an example, and the distance or spacing between the strips may be approximately 1-2 mil, for example. That is, the individual strips 422 are spaced apart from each other by material having the first dielectric constant. Generally, the higher the dk value, the higher the coupling of electromagnetic energy to the material with the higher dk value. The strips 422 of lower dielectric constant (air or other dielectric material) in the second portion 420 of the cable 400 creates a desired disruption in coupling of electromagnetic energy towards the shield 410 resulting from signals through the conductors 412 and 414, which as a result, induces more coupling of the electromagnetic energy between the conductors 412 and 414. Said another way, providing dielectric material with a lower dk around an inner surface of the shield 410 induces lower conductor-to-shield coupling of electromagnetic energy, and greater conductor-to-conductor coupling of electromagnetic energy.

The non-homogeneity of the dielectric body in a cable makes even and odd mode signals travel with different velocities. This is shown by the plots 500 of FIG. 5, where curve 510 is for an odd mode and curve 512 is for an even mode. As can be seen in FIG. 5, the curves 510 and 512 indicate that the odd mode signals and even mode signals travel with different velocities. This creates greater coupling between the signals in the first and second conductors of the cable shown in FIG. 4, which in turn reduces skew, which in turn reduces insertion loss.

Again, the different dielectric properties created around the interior surface of the shield 410 of the cable 400 disrupts the coupling of the electromagnetic field/energy to the shield 410 and consequently encourages/induces more of the field/energy coupling between the conductors 412 and 414.

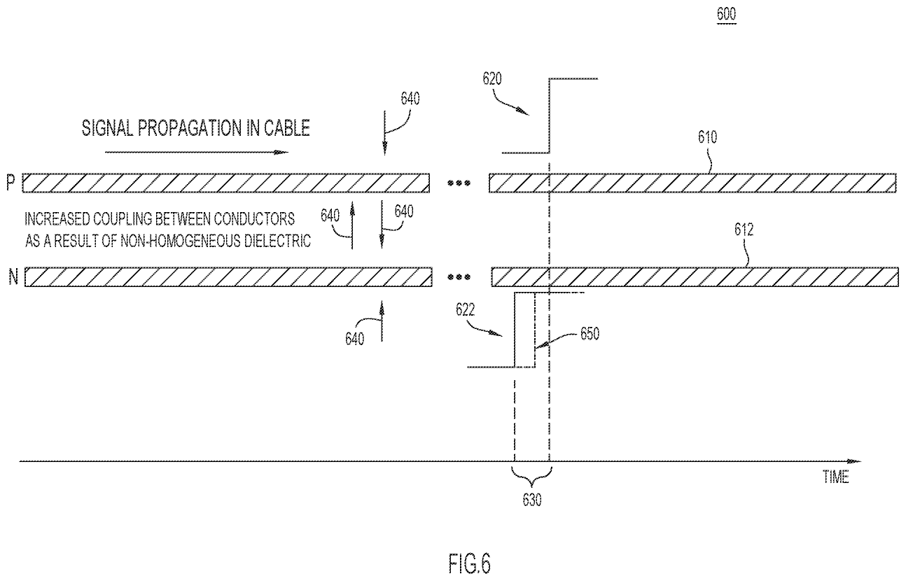

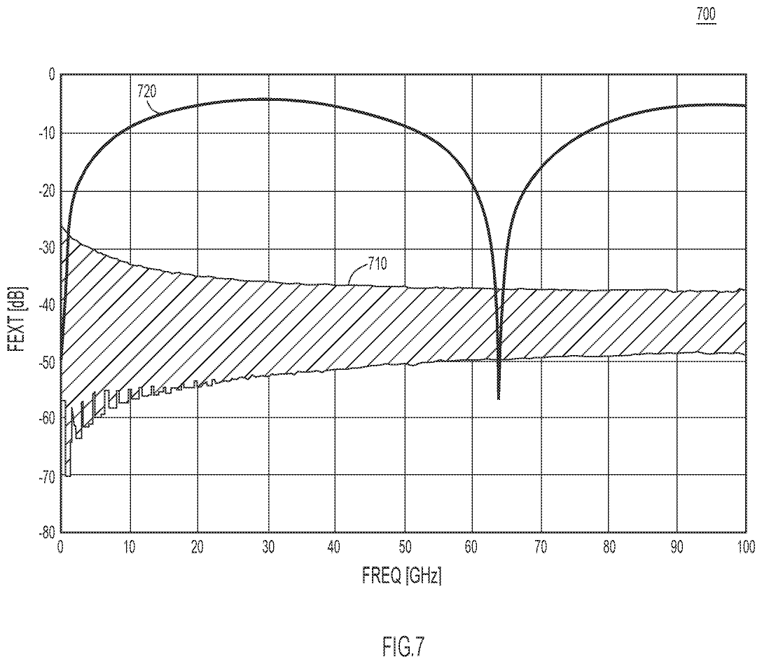

FIG. 6 provides a diagrammatic depiction 600 of the impact of greater coupling between conductors in a cable (or between conductive traces in a stripline PCB). The conductors are shown at reference numerals 610 and 612, where conductor 610 carries the positive (P) signal of a differential signal pair and conductor 612 carries the negative (N) signal of the differential signal pair. Signals propagate from left to right through the conductors 610 and 612. FIG. 6 shows a portion of a waveform of a P signal 620 traveling through conductor 610 and a portion of a waveform of an N signal 622 traveling through conductor 612, with respect to a time scale. As shown, there is a timing lag or skew 630 between the P signal 620 and the N signal 622. By increasing the coupling of electromagnetic energy between the conductors 610 and 612, as shown by arrows 640, the N signal 622, which lags the P signal 620, can “catch up” to the P signal 620, thus reducing the skew as shown at 650.

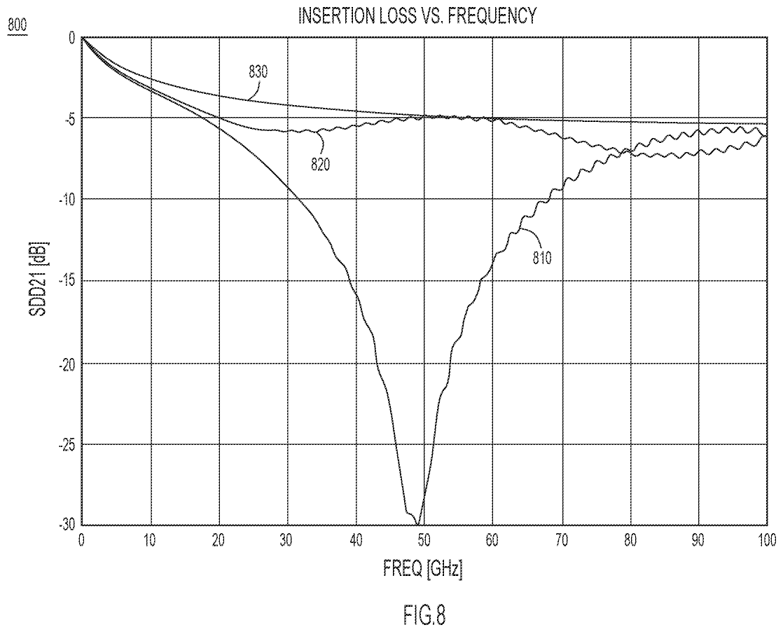

FIG. 7 illustrates plots 700 comparing coupling between P/N signal conductors of a twinax cable having a homogeneous dielectric structure (as shown in FIG. 2) with the coupling between signal P/N conductors of a twinax cable having a non-homogeneous dielectric structure (as shown in FIG. 4). Curve 710 is for a cable with a homogeneous dielectric structure and curve 720 is for a cable with a non-homogeneous dielectric structure.

Similarly, FIG. 8 illustrates plots 800 comparing the skew impact on differential insertion loss between a twinax cable having a homogeneous dielectric structure (as shown in FIG. 2) with a twinax cable having a non-homogeneous dielectric structure (as shown in FIG. 4). Curve 810 is for a cable with a homogeneous dielectric structure (with 10 ps skew), curve 820 is for a cable with a non-homogeneous dielectric structure (with 10 ps skew) and curve 830 is for an ideal cable with no skew.

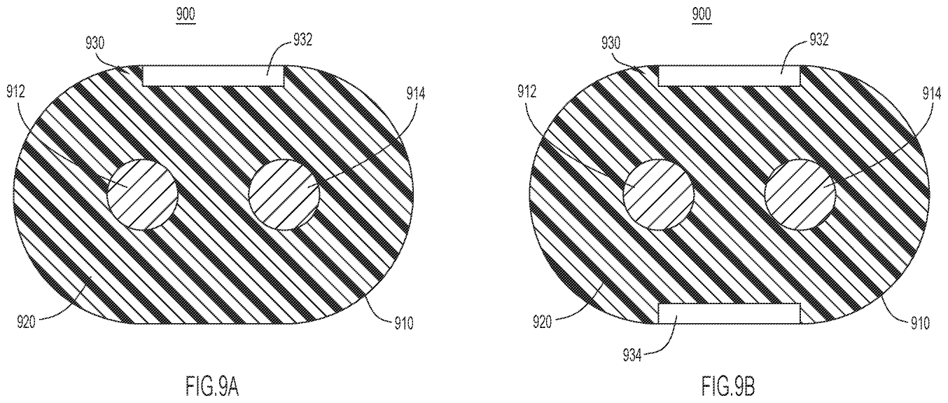

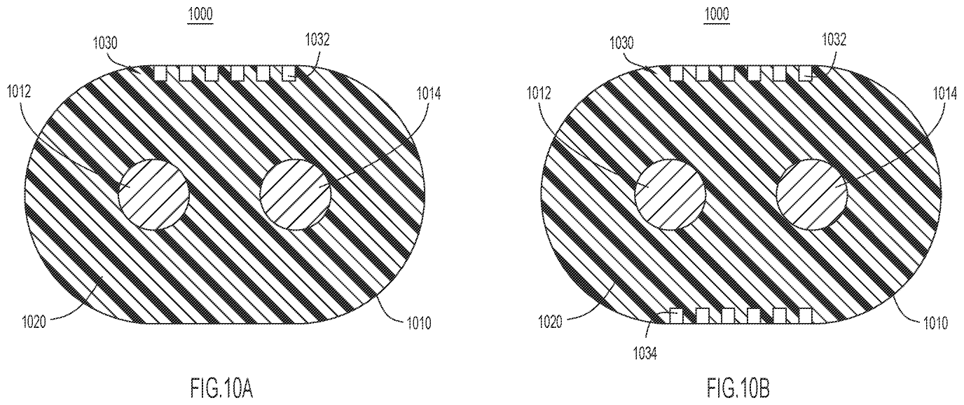

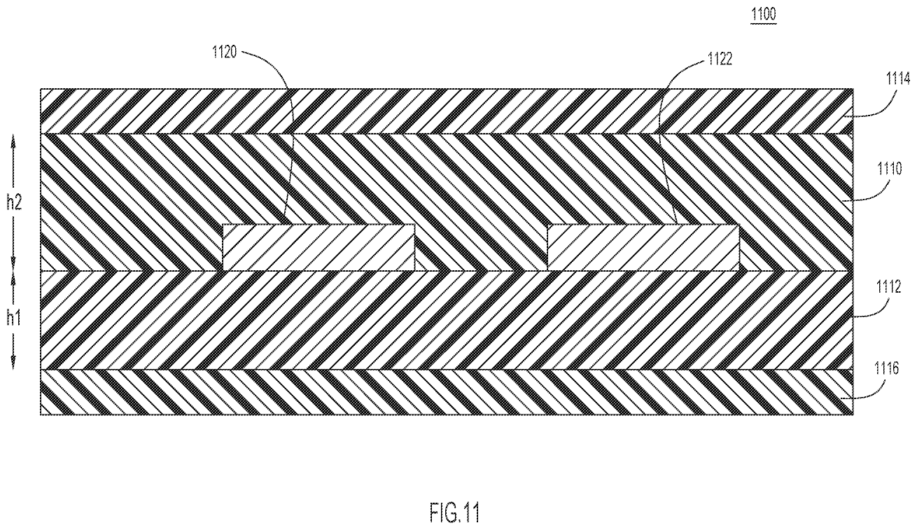

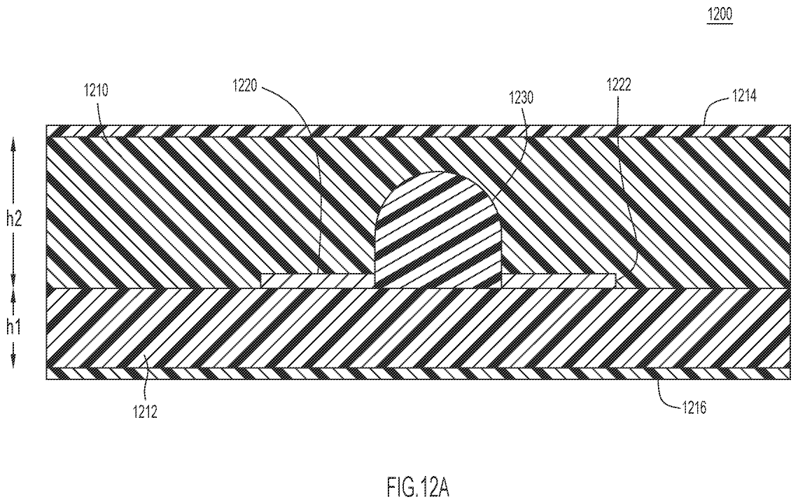

FIGS. 9A, 9B, 10A and 10B illustrate cross-section views showing variations to the sizes and spacing of the strips/stripes created in the dielectric body of a cable to induce a non-homogenous dielectric property/characteristic.

Reference is first made to FIGS. 9A and 9B. FIG. 9A shows a structure for a cable 900 having a shield 910, first and second conductors 912 and 914, and a dielectric body that comprises a first portion 920 with a first dielectric constant and a second portion 930 with a second dielectric constant. The second dielectric constant is less than the first dielectric constant. The second portion 930 comprises a first strip 932 of material with the second dielectric constant. The first strip 932 may be an air gap or a material of a lower dielectric constant than that of the first portion 920. In FIG. 9A, the first strip of material extends along/around a first portion of the periphery of the shield 910 adjacent to an inner surface of the shield 910.

FIG. 9B is similar to FIG. 9A except that the second body portion (of the lower dielectric constant) further includes a second strip 934 (of material with the second dielectric constant) that extends along/around a second portion of the periphery of the shield 910 adjacent to an inner surface of the shield 910. In one example, as shown in FIG. 9B, the first strip 932 and the second strip 934 are on opposite sides of the inner surface of the periphery of the shield 910. This is only example. The locations of the first strip 932 (and the second strip 934) may be selected to control the coupling of electromagnetic energy (away from the shield 910 and instead toward the first and second conductors 912 and 914).

Reference is now made to FIGS. 10A and 10B. FIG. 10A shows a structure for a cable 1000 having an outer shield 1010, first and second conductors 1012 and 1014, and a dielectric body that comprises first portion 1020 with a first dielectric constant and a second portion 1030 with a second dielectric constant. The second portion 1030 comprises a first plurality of strip (or stripes) 1032 of material with the second dielectric constant. The first plurality of strips 1032 may be air gaps or a material of a lower dielectric constant than that of the first portion 1020, spaced apart from each other by material of the first dielectric constant. In FIG. 10A, the first plurality of strips 1032 extends along/around a first portion of the periphery of the shield 1010 adjacent to an inner surface of the shield 1010. (As shown in FIG. 4, the plurality of strips may extend around an entirety of the periphery of the shield.)

FIG. 10B is similar to FIG. 10A except that the second body portion (of the lower dielectric constant) further includes a second plurality of strips 1034 (of material with the second dielectric constant) that extends along/around a second portion of the periphery of the shield 1010 adjacent to an inner surface of the shield 1010. The second plurality of strips 1034 may be air gaps or a material of a lower dielectric constant than that of the first portion 1020, with the individual strips being spaced apart from each other by material of the first dielectric constant. In one example, as shown in FIG. 10B, the first plurality of strips 1032 and the second plurality of strips 1034 are on opposite sides of the inner surface of the periphery of the shield 1010. This is only example. The locations of the first plurality of strips 1032 (and the second plurality of strips 1034) may be selected to control the coupling of electromagnetic energy (away from the shield 1010 and toward the first and second conductors 1012 and 1014).

In summary, the arrangements described above in connection with FIGS. 1-8, 9A, 9B, 10A and 10B provide for a twinax cable that has a dielectric body with a non-homogenous dielectric property (in cross-section) to improve coupling between the conductors. These configurations achieve this without increasing the cross-sectional size of the cable, which is highly desirable.

The arrangements and concepts behind the configurations presented above for a twinax cable are applicable to reducing skew between differential pairs of conductive signal traces in a stripline PCB. In a stripline PCB, it is desired to create tightly coupled differential stripline pairs (large coupling between P and N conductive signal traces of a differential pair) to mitigate skew and minimize its impact. Skew compensation is caused by energy transfer to the trace (N) (in which the signal may be delayed from the signal in the other signal trace (P), as described above in connection with FIG. 6. The coupling benefits for a stripline PCB are the same as those for a cable, as shown in FIGS. 7 and 8, and described above.

Several arrangements are described below for creating strong coupling between conductive signal traces in a stripline PCB.

A first arrangement is described with reference to FIG. 11. In this arrangement, the pre-pregnated (pre-preg) dielectric layer and the core dielectric layer have different dielectric constants. FIG. 11 illustrates a cross-sectional view of a stripline PCB 1100. The stripline PCB 1100 includes a pre-pregnated dielectric layer 1110, a core dielectric layer 1112, and top and bottom ground plane shield layers 1114 and 1116, respectively. Conductive signal traces 1120 and 1122 are formed at the bottom of the dielectric layer 1110. The core dielectric layer 1112 may have a height h1, which is less than a height h2 of the pre-pregnated dielectric layer 1110. That is, the pre-pregnated dielectric layer 1110 has a greater thickness than a thickness of the core dielectric layer 1112. The conductive signal traces 1220 and 1222 are separated by space S and have a width W. In one example, the dielectric constant (dk) of the core dielectric layer 1112 is 2.5 and the dielectric constant of the pre-pregnated dielectric layer is 3.5. In one example, the height h1 of the core dielectric layer 1112 may be 4 mil and the height of the pre-pregnated dielectric layer 1110 may be 6 mil. By making the height of the pre-pregnated dielectric layer 1110 greater than the height of the core dielectric layer 1112, and making the dielectric constant of the pre-pregnated dielectric layer 1110 to be greater than the dielectric constant of the core dielectric layer 1112, the coupling of electromagnetic energy is induced to be more towards the central area of the stripline PCB where the conductive traces 1120 and 1122 are located, rather than towards the bottom into the core dielectric layer 1112.

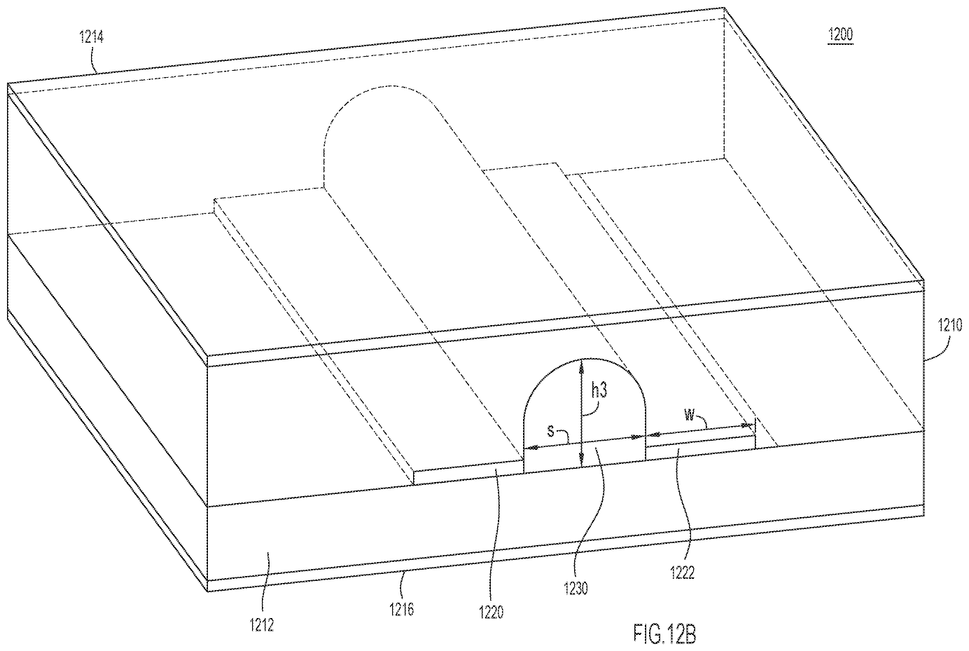

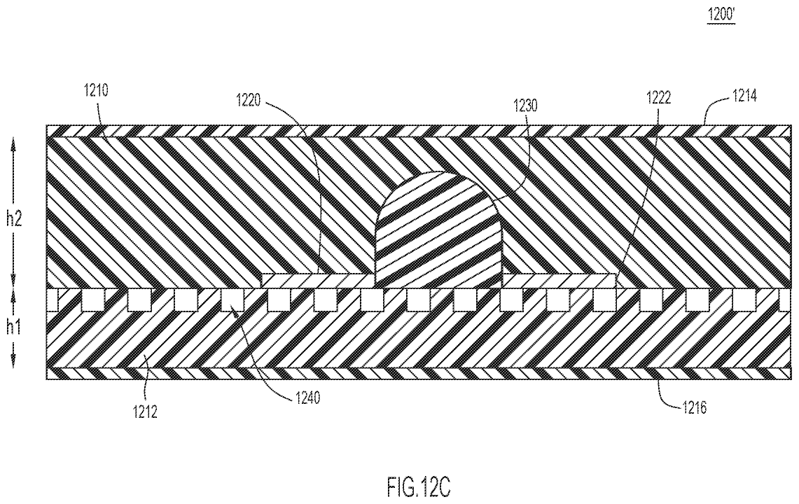

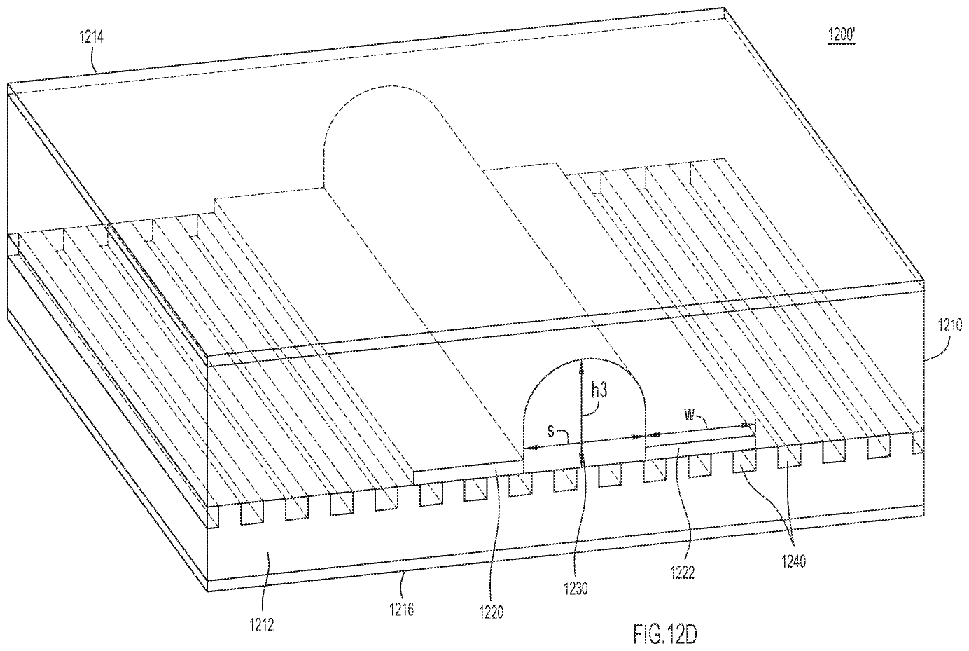

Reference is now made to FIGS. 12A and 12B. FIG. 12A illustrates a cross-sectional view of a stripline PCB 1200 according to an example embodiment, and FIG. 12B is a transparent perspective view of the stripline PCB 1200. The stripline PCB 1200 includes a pre-pregnated dielectric layer 1210, a core dielectric layer 1212, and top and bottom ground plane shield layers 1214 and 1216, respectively. Conductive signal traces 1220 and 1222 are formed at the bottom of the dielectric layer 1210. The core dielectric layer 1212 may have a height h1 (e.g., 4 mil), which is less than a height h2 (e.g., 6 mil) of the pre-pregnated dielectric layer 1210. That is, the pre-pregnated dielectric layer 1210 has a greater thickness than a thickness of the core dielectric layer 1212. The conductive signal traces 1220 and 1222 are separated by space S and have a width W. In the space between the conductive signal traces 1220 and 1222, a dielectric strip 1230 (also called a bubble) is provided that occupies the space S and extends a height h3 (e.g., 5 mil) above the bottom of the pre-pregnated dielectric layer 1210, thus more than half the thickness of the pre-pregnated dielectric layer 1210. The dielectric strip 1230 may have a rounded semicircular shape at a top surface portion, forming the aforementioned “quasi-bubble” shape. The pre-pregnated dielectric layer 1210 and the core dielectric layer 1212 may have the same dielectric constant (e.g., 4) or may have different dielectric constants (as described above in connection with FIG. 11). The dielectric strip 1230 has a smaller dielectric constant than that of the pre-pregnated dielectric layer 1210 and the core dielectric layer 1212. For example, the dielectric strip 1230 may be made of Teflon® which has a dielectric constant of 2.1. The arrangement of FIGS. 12A and 12B create higher coupling towards the stripline conductive traces.

Reference is now made to FIGS. 12C and 12D, which illustrate a stripline PCB 1200′ that is similar to the stripline PCB 1200 shown in FIGS. 12A and 12B, but includes one additional structural feature. Specifically, the stripline PCB 1200′ includes a plurality of strips/stripes 1240 of air gaps or other dielectric material having a lower dielectric constant than that the core dielectric layer 1212 and the pre-pregnated dielectric layer 1210. The addition of the strips 1240 further encourages coupling of electromagnetic energy away from the bottom of the stripline PCB and more towards the conductive signal traces 1220 and 1222.

In some aspects, the techniques described herein relate to an apparatus including: a dielectric body; first and second conductors within the dielectric body spaced apart from each other; and a shield around a periphery of the dielectric body, wherein the dielectric body has, in cross-section, a non-homogenous dielectric property configured to enhance coupling of electromagnetic energy between the first and second conductors when signals are carried by the first and second conductors.

In some aspects, the techniques described herein relate to an apparatus, wherein the apparatus is a cable and the dielectric body includes, in cross-section, a first portion with a first dielectric constant and a second portion with a second dielectric constant different from the first dielectric constant, wherein the second portion is proximate to an inner surface of the shield and the second dielectric constant is less than the first dielectric constant so as to disrupt coupling of electromagnetic energy towards the shield and thereby enhance coupling of electromagnetic energy between the first and second conductors.

In some aspects, the techniques described herein relate to an apparatus, wherein the second portion includes at least a first strip including an air gap or a material with the second dielectric constant.

In some aspects, the techniques described herein relate to an apparatus, wherein the first strip extends around a first portion of the periphery.

In some aspects, the techniques described herein relate to an apparatus, wherein the second portion further includes a second strip including an air gap or a material with the second dielectric constant, wherein the second strip extends around a second portion of the periphery.

In some aspects, the techniques described herein relate to an apparatus, wherein the first strip extends around an entirety of the periphery.

In some aspects, the techniques described herein relate to an apparatus, wherein the second portion includes a first plurality of strips of air gaps or a material with the second dielectric constant, wherein individual strips of the first plurality of strips are spaced apart from each other by material having the first dielectric constant.

In some aspects, the techniques described herein relate to an apparatus, wherein the first plurality of strips extend around a first portion of the periphery.

In some aspects, the techniques described herein relate to an apparatus, wherein the second portion further includes a second plurality of strips of air gaps or a material with the second dielectric constant, wherein individual strips of the second plurality of strips are spaced apart from each other by material having the first dielectric constant, and wherein the second plurality of strips extend around a second portion of the periphery.

In some aspects, the techniques described herein relate to an apparatus, wherein the first plurality of strips extend around an entirety of the periphery.

In some aspects, the techniques described herein relate to an apparatus, wherein the apparatus is a stripline printed circuit board, and wherein the first and second conductors are first and second conductive signal traces in the dielectric body.

In some aspects, the techniques described herein relate to an apparatus, wherein the dielectric body includes, in cross-section, a first dielectric layer having a first dielectric constant and a second dielectric layer having a second dielectric constant, wherein the first and second conductive signal traces are formed in the first dielectric layer and the second dielectric layer is adjacent the first dielectric layer, wherein the first dielectric constant is greater than the second dielectric constant.

In some aspects, the techniques described herein relate to an apparatus, wherein the first dielectric layer has a thickness that is greater than a thickness of the second dielectric layer.

In some aspects, the techniques described herein relate to an apparatus, wherein the dielectric body includes, in cross-section, a first dielectric layer having a first dielectric constant and a second dielectric layer having a first dielectric constant, wherein the first and second conductive signal traces are formed in the first dielectric layer and the second dielectric layer is adjacent the first dielectric layer, and further including a dielectric strip disposed between the first and second conductive signal traces, the dielectric strip having a second dielectric constant that is less than the first dielectric constant.

In some aspects, the techniques described herein relate to an apparatus, wherein the dielectric strip has a rounded semicircular shape at a top portion thereof and a thickness that is more than half of a thickness of the first dielectric layer.

In some aspects, the techniques described herein relate to an apparatus, further including a plurality of strips beneath the first dielectric layer that extend into the second dielectric layer, the plurality of strips including spaced apart air gaps or a material having a dielectric constant less than the first dielectric constant.

In some aspects, the techniques described herein relate to an apparatus including: a dielectric body; a shield around a periphery of the dielectric body; and first and second conductors within the dielectric body spaced apart from each other, wherein the dielectric body includes, in cross-section, a dielectric material having a first dielectric constant, and one or more strips along at least a portion of the periphery of the dielectric body adjacent to an inner surface of the shield, the one or more strips included of air gaps in the dielectric material or a different dielectric material having a second dielectric constant less than the first dielectric constant.

In some aspects, the techniques described herein relate to an apparatus, wherein the apparatus is a twinaxial cable, and the one or more strips extend around a first portion of the periphery.

In some aspects, the techniques described herein relate to an apparatus, wherein the one or more strips include a plurality of spaced apart strips around an entirety of the periphery.

In some aspects, the techniques described herein relate to an apparatus including: a dielectric body having a non-homogeneous dielectric property in cross-section; first and second conductors within the non-homogeneous dielectric body; and a shield containing the dielectric body.

In some aspects, the techniques described herein relate to an apparatus, wherein the dielectric body includes a first portion having a first dielectric constant and one or more strips of air gaps or a material of a different dielectric constant than the first dielectric constant, wherein the one or more strips are positioned around at least a portion of a periphery of the first portion adjacent to an inner surface of the shield.

In some aspects, the techniques described herein relate to an apparatus, wherein the dielectric body includes, in cross-section, a first dielectric layer having a first dielectric constant and a second dielectric layer having a second dielectric constant, wherein the first and second conductors are first and second conductive signal traces formed in the first dielectric layer and the second dielectric layer is adjacent the first dielectric layer, wherein the first dielectric constant is greater than the second dielectric constant.

In some aspects, the techniques described herein relate to an apparatus, wherein the dielectric body includes, in cross-section, a first dielectric layer having a first dielectric constant and a second dielectric layer having a first dielectric constant, wherein the first and second conductors are first and second conductive signal traces formed in the first dielectric layer and the second dielectric layer is adjacent the first dielectric layer, and further including a dielectric strip disposed between the first and second conductive signal traces, the dielectric strip having a second dielectric constant that is less than the first dielectric constant.

In some aspects, the techniques described herein relate to an apparatus, further including a plurality of strips beneath the first dielectric layer that extend into the second dielectric layer, the plurality of strips including spaced apart air gaps or a material having a dielectric constant less than the first dielectric constant.

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of can be represented using the’ ‘(s)’ nomenclature (e.g., one or more element(s)).

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/−5%, within +/−4%, within +/−3%, within +/−2%, within +/−1%, or even closer, of the given value. Similarly, when a given feature is described as being “substantially parallel” to another feature, “generally perpendicular” to another feature, and so forth, this is intended to convey that the given feature is within +/−5%, within +/−4%, within +/−3%, within +/−2%, within +/−1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree, but may have minor deviation from exactly parallel.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. An apparatus comprising:
a dielectric body;
first and second conductors within the dielectric body spaced apart from each other; and
a shield around a periphery of the dielectric body,
wherein the dielectric body has, in cross-section, a non-homogenous dielectric property configured to enhance coupling of electromagnetic energy between the first and second conductors when signals are carried by the first and second conductors.

2. The apparatus of claim 1, wherein the apparatus is a cable and the dielectric body comprises, in cross-section, a first portion with a first dielectric constant and a second portion with a second dielectric constant different from the first dielectric constant, wherein the second portion is proximate to an inner surface of the shield and the second dielectric constant is less than the first dielectric constant so as to disrupt coupling of electromagnetic energy towards the shield and thereby enhance coupling of electromagnetic energy between the first and second conductors.

3. The apparatus of claim 2, wherein the second portion comprises at least a first strip comprising an air gap or a material with the second dielectric constant.

4. The apparatus of claim 3, wherein the first strip extends around a first portion of the periphery.

5. The apparatus of claim 4, wherein the second portion further comprises a second strip comprising an air gap or a material with the second dielectric constant, wherein the second strip extends around a second portion of the periphery.

6. The apparatus of claim 3, wherein the first strip extends around an entirety of the periphery.

7. The apparatus of claim 2, wherein the second portion comprises a first plurality of strips of air gaps or a material with the second dielectric constant, wherein individual strips of the first plurality of strips are spaced apart from each other by material having the first dielectric constant.

8. The apparatus of claim 7, wherein the first plurality of strips extend around a first portion of the periphery.

9. The apparatus of claim 7, wherein the second portion further comprises a second plurality of strips of air gaps or a material with the second dielectric constant, wherein individual strips of the second plurality of strips are spaced apart from each other by material having the first dielectric constant, and wherein the second plurality of strips extend around a second portion of the periphery.

10. The apparatus of claim 7, wherein the first plurality of strips extend around an entirety of the periphery.

11. The apparatus of claim 1, wherein the apparatus is a stripline printed circuit board, and wherein the first and second conductors are first and second conductive signal traces in the dielectric body.

12. The apparatus of claim 11, wherein the dielectric body comprises, in cross-section, a first dielectric layer having a first dielectric constant and a second dielectric layer having a second dielectric constant, wherein the first and second conductive signal traces are formed in the first dielectric layer and the second dielectric layer is adjacent the first dielectric layer, wherein the first dielectric constant is greater than the second dielectric constant.

13. The apparatus of claim 12, wherein the first dielectric layer has a thickness that is greater than a thickness of the second dielectric layer.

14. The apparatus of claim 11, wherein the dielectric body comprises, in cross-section, a first dielectric layer having a first dielectric constant and a second dielectric layer having a first dielectric constant, wherein the first and second conductive signal traces are formed in the first dielectric layer and the second dielectric layer is adjacent the first dielectric layer, and further comprising a dielectric strip disposed between the first and second conductive signal traces, the dielectric strip having a second dielectric constant that is less than the first dielectric constant.

15. The apparatus of claim 14, wherein the dielectric strip has a rounded semicircular shape at a top portion thereof and a thickness that is more than half of a thickness of the first dielectric layer.

16. The apparatus of claim 14, further comprising a plurality of strips beneath the first dielectric layer that extend into the second dielectric layer, the plurality of strips comprising spaced apart air gaps or a material having a dielectric constant less than the first dielectric constant.

17. An apparatus comprising:
a dielectric body;
a shield around a periphery of the dielectric body; and
first and second conductors within the dielectric body spaced apart from each other,
wherein the dielectric body comprises, in cross-section, a dielectric material having a first dielectric constant, and one or more strips along at least a portion of the periphery of the dielectric body adjacent to an inner surface of the shield, the one or more strips comprised of air gaps in the dielectric material or a different dielectric material having a second dielectric constant less than the first dielectric constant.

18. The apparatus of claim 17, wherein the apparatus is a twinaxial cable, and the one or more strips extend around a first portion of the periphery.

19. The apparatus of claim 18, wherein the one or more strips comprise a plurality of spaced apart strips around an entirety of the periphery.

20. An apparatus comprising:
a dielectric body having a non-homogeneous dielectric property in cross-section;
first and second conductors within the dielectric body; and
a shield containing the dielectric body.

21. The apparatus of claim 20, wherein the dielectric body comprises a first portion having a first dielectric constant and one or more strips of air gaps or a material of a different dielectric constant than the first dielectric constant, wherein the one or more strips are positioned around at least a portion of a periphery of the first portion adjacent to an inner surface of the shield.

22. The apparatus of claim 20, wherein the dielectric body comprises, in cross-section, a first dielectric layer having a first dielectric constant and a second dielectric layer having a second dielectric constant, wherein the first and second conductors are first and second conductive signal traces formed in the first dielectric layer and the second dielectric layer is adjacent the first dielectric layer, wherein the first dielectric constant is greater than the second dielectric constant.

23. The apparatus of claim 20, wherein the dielectric body comprises, in cross-section, a first dielectric layer having a first dielectric constant and a second dielectric layer having a first dielectric constant, wherein the first and second conductors are first and second conductive signal traces formed in the first dielectric layer and the second dielectric layer is adjacent the first dielectric layer, and further comprising a dielectric strip disposed between the first and second conductive signal traces, the dielectric strip having a second dielectric constant that is less than the first dielectric constant.

24. The apparatus of claim 23, further comprising a plurality of strips beneath the first dielectric layer that extend into the second dielectric layer, the plurality of strips comprising spaced apart air gaps or a material having a dielectric constant less than the first dielectric constant.
